(19) United States
(12) Patent Application Publication
(10) Pub. No.: US 2021/0203303 A1
(43) Pub. Date: Jul. 1, 2021

(54) BAW RESONATOR WITH COIL INTEGRATED IN HIGH IMPEDANCE LAYER OF BRAGG MIRROR OR IN ADDITIONAL HIGH IMPEDANCE METAL LAYER BELOW RESONATOR

(71) Applicant: RF360 EUROPE GMBH, Munchen (DE)

(72) Inventors: Maximilian SCHIEK, Munchen (DE); Willi AIGNER, Munchen (DE); Thomas MITTERMAIER, Munchen (DE)

(21) Appl. No.: 17/268,065

(22) PCT Filed: Aug. 12, 2019
(86) PCT No.: PCT/EP2019/071571

§ 371 Date: Feb. 11, 2021

(30) Foreign Application Priority Data
Sep. 5, 2018 (DE) 102018121689.0

(51) Int. Cl. H03H 9/17; H03H 9/13

(52) U.S. Cl. CPC H03H 9/175; H03H 9/13

(57) ABSTRACT

It is proposed to enhance the bandwidth of a SMR BAW resonator (TE,PL,BE) by circuiting it with a planar coil (WG1, WG2) that is realized in a high impedance layer (HI) of the Bragg mirror (BM) or in an additional metal layer below the Bragg mirror.

Wide-band filter applications require resonators with a high pole-zero distance (PZD), i.e. frequency spacing between main or series resonance and parallel or antiresonance frequencies. The pole-zero distance PZD is directly related to the effective piezoelectric coupling and hence to intrinsic material properties and the structure of the layer stack the resonator consists of. Especially 5G applications (5th generation wireless systems) require bandwidths far exceeding those bandwidths that are achievable with state of the art micro-acoustic resonators used in a typical ladder type filter design. Hence, non-standard topologies are needed which in many cases require many inductors, often in series or parallel to a micro-acoustic resonator.

To widen the pole-zero distance (PZD) of BAW resonators, inductors can be added in series. Thereby the series resonance can be shifted to a lower frequency position. Alternatively by using a parallel inductor the parallel- or antiresonance can be shifted to a higher frequency position. Usually, these inductors are realized as external elements (e.g. SMDs, POGs) that can be arranged on-chip next to a BAW resonator. Hence, these external elements require additional space. Alternatively the coils can be integrated within a laminate or package the BAW resonator is mounted to or packaged in.

It is an object of the present application to realize the combination of lumped elements like inductors and a micro-acoustic resonator in a compact way and with minimal interconnection lengths.

This and other objects are met by the BAW resonator of claim 1. Advantageous features and embodiments of such a BAW resonator are given by dependent claims.

A BAW resonator of the SMR type (solidly mounted resonator) comprises a substrate, a Bragg mirror, a bottom electrode, a piezoelectric layer and a top electrode. The Bragg mirror serves to keep the acoustic energy inside the resonator and comprises alternating mirror layers of high acoustic impedance and low acoustic impedance. A fundamental reflecting effect is achieved with one pair of mirror layers. Advantageously two pairs of mirror layers or an uneven number of mirror layers is used to completely reflect the wave back into the resonator.

It is proposed to realize an inductor as a planar coil below the active resonator region in a high impedance mirror layers or an additional metal layer arranged between substrate and Bragg mirror. To achieve sufficient reflection at least two high impedance layers are present.

The planar coil is electrically connected to the resonator that is to at least one of the resonator's electrodes.

Such a solution has only minimal space consumption as the integration of a planar coil into an already existing stack of similar layers is easy and synergy effects can be used. Structuring of high impedance mirror layers is necessary too and hence, the structuring of the planar coil can be done the same way.

The BAW resonator comprises at least two high impedance mirror layers. If the coil is structured from one of these layers the reflecting effect of the so-produced coil of high acoustic impedance material can be used advantageously.

However it is preferred to use at least one pair or two pairs of complete mirror layers without coils and to arrange or structure the coil in an additional metal layer. This additional metal layer may be a high impedance layer and may comprise the same material like the high impedance mirror layers. Then, the manufacturing process becomes simpler.

However any other electrically conductive metal of any acoustic impedance can be used for the additional metal layer if the reflecting effect of the complete mirror layers of the Bragg mirror above is sufficiently high. High impedance mirror layers as well as the metal layer with the coil structured therefrom are embedded in a low impedance dielectric material. Then, the planar coil has no detrimental effect onto the acoustic of the resonator and hence on the Q factor thereof.

According to an embodiment the BAW resonator comprises two additional metal layers with a respective first and second planar coil formed therein. First and second planar coil are circuited in series with each other. This can be done by connecting a respective first end of each of the two windings that form the coils by a vertical through contact e.g. a via. The respective other second ends are used to connect the coils in series or parallel to the resonator via at least one of the resonator's electrodes. These connections too can be realized by a respective via. The vias are guided through the mirror layers. Preferably the vias are formed at a position that is outside the active resonator area. An active resonator region is defined to be a region where bottom electrode, piezoelectric layer and top electrode overlap each other. An active resonator area is defined to be the area of the active resonator region when projected normal to the top surface of the substrate. If the vias are arranged outside the active resonator area no acoustic interaction with the resonator and hence, no detrimental effect occurs.

The planar coil is a planar winding that has a first end in the middle of the winding and a second end. The first end is connected by a first via to a first electrode of the resonator and the second end of the planar coil is connected by a second via to the second electrode of the resonator. First and second electrode are selected from bottom electrode and top electrode.

If the coil comprises two planar windings it is preferred to arrange the windings directly one above the other with an intermediate dielectric. The two windings are then coupled and circuited in series by connecting their first ends with a via. The advantage is that the second ends at the respective periphery of the windings can easily be coupled to a first and a second electrode selected from bottom electrode and top electrode directly by a first and a second via or by interposing an outwardly guided conductor line. Then the via is located outside the active resonator area.

Material properties and layer thicknesses of the layer stack of the BAW resonator are very well controlled for optimal acoustic behavior which is more demanding than the electromagnetic properties. Inductors (i.e. the planar coils) are shaped using the same photolithographic steps that are anyway needed to pattern the high-impedance mirror layers. High impedance mirror layers may be restricted in area to the active resonator area such that mirror layers of neighbored resonators are electrically isolated against each other to avoid EM crosstalk between these resonators that would otherwise ultimately reduce the filter selectivity.

The manufacture of the proposed BAW resonator requires only low process variation compared to other solutions and processes where external lumped elements need to be realized and coupled e.g. integrated into laminates, or embodied as PoG (passives on glass).

Bragg mirror as well as electrode, piezoelectric layer and package if required can be embodied according to the art as these components do not interact with the proposed planar coil. The material of the high impedance layers can comprise a high impedance metal chosen from W and Mo. As a material of the low impedance and dielectric layers silicon dioxide is a preferred choice due to its proved properties and easy handling.

Independent therefrom the materials of the electrodes of the resonator can be chosen from a group comprising W and Mo. Manufacture of the complete layer stack may be simplified if the same metal is used for mirror layer and electrodes. However, better electrical conductivity of molybdenum Mo or Al may make Mo or Al a preferred choice for the electrodes. If a high impedance mirror layer is targeted W may be preferred in view of the higher_impedance of tungsten W.

The piezoelectric layer may consist of AlN. However, ZnO and AlN doped with Sc may be used too.

On top of the top electrode a passivation layer of SiN may be deposited. If necessary a mechanically stable capping may complete the BAW resonator. Such a capping may comprise a capping layer integrally formed on the top surface thereby keeping an air-filled cavity above the active resonator region. The cavity may be pre-formed as a sacrificial layer that is structured that sacrificial material remains only on those surface areas that need to be protected in a cavity under a capping layer. The cavity can be released after depositing the capping layer and removing the structured material of the sacrificial layer through release holes made in the capping layer.

A BAW resonator is mainly used for creating RF filters by circuiting such resonators in a ladder type arrangement according to the art. The resonators of such an arrangement are circuited in series and parallel by top electrode connection and/or bottom electrode connection. According to the specifications the filter must attend to, the bandwidth of the resonators need to be adapted by coupling inductors to the resonators as proposed. In a filter circuit, at least as many inductors as BAW resonators can be realized within one filter die i.e. on a single substrate chip.

Measures can be taken to avoid crosstalk between different resonators on the same chip. For doing so metal layers can be grounded to shield the coil in a vertical direction. A kind of fence of long vias arranged at the perimeter of the active resonator area may shield the coil in a horizontal direction.

In the following the invention will be explained in more detail with reference to preferred embodiments and the accompanied figures. The figures are schematic only and are not drawn to scale. Hence, neither relative nor absolute geometry parameters can be taken from the figures.

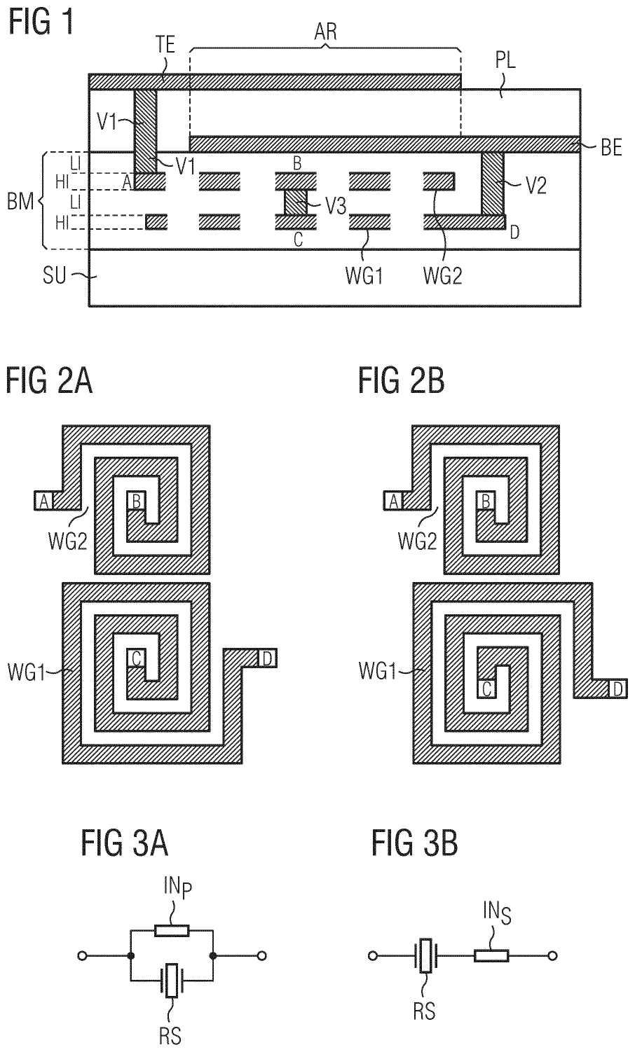

FIG. 1 shows a BAW resonator with two high impedance windings.

FIGS. 2A and 2B show different way two interconnect two windings of a 3D coil.

FIGS. 3A and 3B show two possibilities to interconnect a BAW resonator and an inductor.

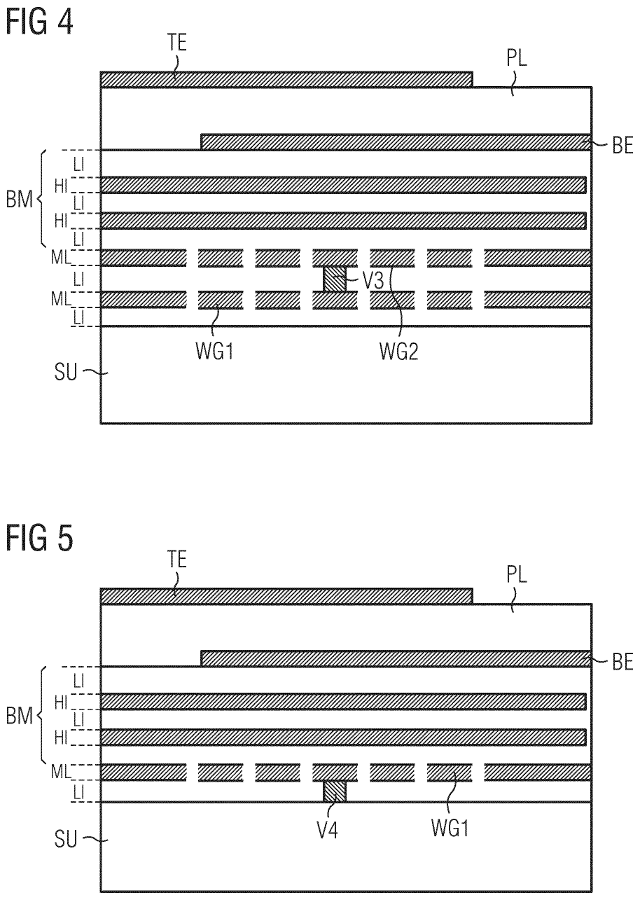

FIG. 4 shows a BAW resonator with a Bragg mirror and two additional metal layers including a winding each.

FIG. 5 shows a BAW resonator with a Bragg mirror and one additional metal layer including a winding.

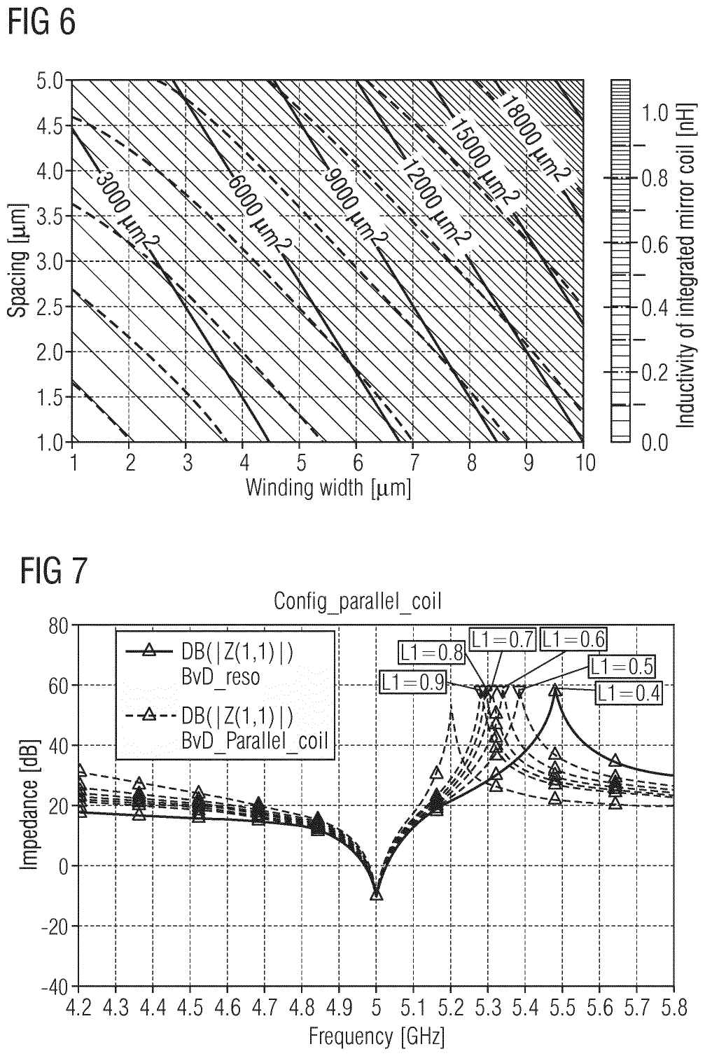

FIG. 6 shows in a diagram the dependency of the inductance of a coil from the spacing and the width of the winding.

FIG. 7 shows the impedance of a BAW resonator circuited in parallel with an inductor with different values of inductance.

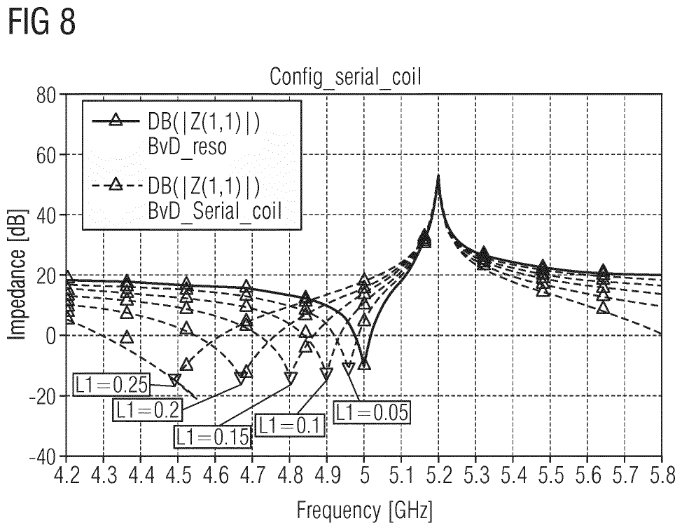

FIG. 8 shows the impedance of a BAW resonator circuited in series with an inductor with different values of inductance.

FIG. 1 shows a BAW resonator of the SMR type in a schematic cross section. On a substrate SU e.g. of silicon a Bragg mirror BM is formed. A bottom electrode BE e.g. of Mo, a piezoelectric layer e.g. of AlN that may be doped with e.g. Sc. A top electrode TE e.g. of Mo are formed as a sandwich over the Bragg mirror. The Bragg mirror comprises two high impedance layers HI e.g. of W each embedded in a low impedance layer LI of SiO₂. Hence, five mirror layers or 2.5 mirror layer pairs form the acoustic reflector.

At least one of the high impedance layers HI comprises a planar coil that is structured as a winding WG in the high impedance layer HI. FIG. 1 shows two windings WG1,WG2 that are circuited in series with each other by a third via V3 that connects the first ends B and C in the respective middle of each winding WG1,WG2. The second end D of the first winding WG1 that is the lower one is connected to the bottom electrode BE by a second via V2. The second end A of the second winding WG2 that is the upper one is coupled to the top electrode TE by a first via V1. Thereby the resonator is circuited in parallel with the planar coils WG1 and WG2 (see also FIG. 3A).

An active resonator region AR is the region where all three layers of the sandwich overlap each other. Only in the active resonator region AR acoustic waves can be excited and propagate.

The windings are arranged under the active resonator region AR. Depending on the required inductance of the planar coil the area the windings WG occupy may be smaller than the active resonator region AR, equal or, in an extreme case, may extend over the active resonator region AR. In all cases the high impedance layer HI the windings are formed to function as a mirror layer and have a respective thickness of about a quarter wavelength of the acoustic wave.

FIGS. 2A and 2B show different ways to interconnect the two windings WG1, WG1 that form a 3D coil. The second winding WG2 is shown to be the top one. It has a first end B and a second end A. The first winding WG1 has a first end C and a second end D.

When interconnecting both windings of FIG. 2A via their first ends B, C in the respective middles thereof and applying an electric signal over the second ends A, D a magnetic field of a first direction is formed by the first winding and a magnetic field of a second direction opposite to the first direction builds up over and through the second winding. If the two windings WG have the same size the two magnetic fields in the two windings may then partly compensate. A compensated field may be advantageous to avoid magnetic coupling of the windings with other resonators arranged near the regarded resonator.

Depending on the circuiting with the acoustic resonator (series, parallel) and the needed value of the inductor, it may be decided whether to use “aiding” or “opposing” inductors. Furthermore, the inductor design may depend on size constraints and optimal integration with acoustics.

FIG. 2B differs from FIG. 2A in the direction of rotation bottom winding that is mirrored relative to FIG. 2A. As a result, the two magnetic fields can build up in parallel.

FIGS. 3A and 3B show two possibilities to interconnect a BAW resonator RS and inductor IN. In FIG. 3A the BAW resonator RS is circuited in parallel to the inductor IN_{P}. This complies with the embodiment shown in FIG. 1. FIG. 3B shows a series connection of resonator RS and inductor IN_{S}.

FIG. 4 shows another embodiment of a BAW resonator with a Bragg mirror BM and a planar coil arranged below the Bragg mirror comprising two high impedance layers e.g. formed of W and embedded in a layer of low impedance dielectric LI e.g. formed of SiO₂. The inductor comprises two planar coils formed of two interconnected windings WG1, WG2 structured in a first and a second additional metal layer ML. The two additional metal layers ML may also be formed of a high impedance material as W for example but may also comprise any other conductive material. This is because the Bragg mirror already comprises five mirror layers that can reflect the acoustic wave nearly completely. Hence, the additional layers need not act as mirror layers as the acoustic field intensity is very low there.

The two windings of the two additional metal layers are circuited in series similar as those shown in FIG. 1. In the periphery of the windings the metal layers ML are continuous and hence may form a kind of shielding against EM cross talk induced by the coil when a signal is applied to. Electric connections to one or two electrodes of the resonator are present but are not explicitly shown in the figure. If coupled in series according to FIG. 3B one second end may have a termination that is laterally guided out of the active resonator area to an external terminal.

FIG. 5 shows an embodiment of a BAW resonator similar to that of FIG. 4 with a Bragg mirror BM and a planar coil arranged as a winding WG below the Bragg mirror. Different to FIG. 4 the inductor comprises one planar coil only formed out of an additional metal layer ML. This embodiment may be suitable for a series circuit of an inductor IN and the BAW resonator RS.

As the desired widening of the pole zero distance is higher with a parallel inductance having a smaller value only one winding may be sufficient to achieve the desired area that complies with a respective inductance value.

The diagram of FIG. 6 shows the dependency of the inductance value from the size of the winding. Width as well as spacing of the conductor lines that form the winding are proportional to the inductance. As good approach the inductance is proportional to the area of the winding. In the diagram different ranges of inductance are separated by dashed lines. Sections of the same range of area are separated by continuous lines. It can be shown that an inductance of about 1 nH can be achieved with a winding having an area about 1800 μm² or more.

FIG. 7 shows the influence of a coil on the impedance Z11 of the same BAW resonator when circuited in parallel according to FIG. 3A. The anti-resonance frequency according to the maxima shown in the right side of the diagram is shifted towards higher frequencies depending on the inductance value of the coil. At the same time the resonance frequency that is at about 5 GHz in the embodiment keeps constant. As a result the parallel inductor enhances the pole zero distance PZD. In FIG. 7 the value of inductance is varied between 0.9 and 0.4 nH and the largest shift of nearly about 0.5 GHz is achieved here with the lowest inductance. The impedance of the BAW resonator alone complies with the continuous line of the diagram and has the lowest anti-resonance frequency and hence the smallest PZD.

FIG. 8 shows the influence of a coil on the impedance Z11 of a BAW resonator when circuited in series according to FIG. 3B. The resonance frequency according to the minima shown in the left side of the diagram is shifted towards lower frequencies depending on the inductance value of the coil. At the same time the anti-resonance frequency keeps constant at about 5.2 GHz. As a result the parallel inductor enhances the pole zero distance PZD. In FIG. 8 the value of inductance is varied between 0.05 and 0.25 nH and the largest shift of more than 0.5 GHz is achieved here with the highest inductance value. Like in FIG. 7 the impedance of the BAW resonator alone complies with the continuous line of the diagram and has the highest resonance frequency and hence the smallest PZD.

The invention has been shown with reference to selected embodiments only but is not restricted to these embodiments. Materials of the layers, thickness, area and size of the windings may deviate from the depicted or described embodiments. The Bragg mirror may be formed by a deviating number of mirror layers using other high or low impedance materials. The at least one planar coil can be embodied in a high impedance mirror layer or in an additional metal layer below the Bragg mirror. Other substrate materials than silicon may be used too. Besides the shown layers the BAW resonator may comprise further functional layers like thin adhesion supporting layers at the interfaces between two adjacent layers. Depositing at least a passivation layer of e.g. SiN on top of the top electrode according to the art is also self-evident. Further, the BAW resonator may be used in a circuit of several BAW resonators that form a filter circuit in a ladder type arrangement for example. These circuits may be formed by integrally interconnecting neighbored BAW resonators via top electrode or bottom electrode connection which can be done by respective structuring of the electrode layer after deposition.

### LIST OF USED REFERENCE SYMBOLS

RS BAW resonator
BM Bragg mirror layer
HI high-impedance layer
LI low-impedance layer
ML additional metal layer
SU substrate
A,B/C,D first and second end of a winding
WG1,WG2 winding
V1-V3 via
BE bottom electrode
TE top electrode
PL piezoelectric layer
IN_{S}, IN_{P} series and parallel inductor

1. A bulk acoustic wave (BAW) resonator of a solidly mounted resonator (SMR) type, the BAW resonator comprising:
a substrate, a Bragg mirror, a bottom electrode, a piezoelectric layer and a top electrode;
wherein the Bragg mirror comprises alternating mirror layers of high acoustic impedance and low acoustic impedance where at least two high impedance layers are present;
wherein a first planar coil is formed from one of the high impedance mirrors layer or from an additional metal layer arranged between the substrate and a low impedance mirror layer; and
wherein the planar coil is electrically coupled to the resonator.

2. The BAW resonator of claim 1:
wherein the coil is formed from an additional high impedance layer;
wherein the additional high impedance layer and the high impedance mirror layers comprise the same material; and
wherein high impedance layers are embedded between dielectric low-impedance layers.

3. The BAW resonator of claim 1, further comprising:
two additional metal layers with a respective first or second planar coil formed therein, wherein the first and second planar coil are circuited in series with each other.

4. The BAW resonator of claim 1:
wherein the material of the high impedance layers comprises a metal chosen from W, Mo and Al; and
wherein the material of the low impedance layers is silicon oxide.

5. The BAW resonator of claim 1:
wherein an active resonator region is defined to be a region where bottom electrode, piezoelectric layer and top electrode overlap each other;
wherein an active resonator area is the area of the active resonator region when projected normal to the top surface of the substrate; and
wherein the planar coil is coupled to the bottom or top electrode by conducting vias guided through the stack of mirror layer at a position that is outside the active resonator area.

6. The BAW resonator of claim 1:
wherein the planar coil is a planar winding that has a first end in the middle of the winding and a second end; and
wherein the first end is connected by a first via to a first electrode of the resonator and the second end of the planar coil is connected by a second via to the second electrode of the resonator, wherein first and second electrode are selected from bottom electrode and top electrode.

7. The BAW resonator of claim 1:
wherein a respective first planar coil and a respective second planar coil are arranged one above the other but are separated by a low impedance layer of a dielectric; and
wherein the first and second planar coil are circuited in series with each other by a via connecting the first ends in the middles of the respective windings.

8. The BAW resonator of claim 1, wherein the materials of the electrodes of the resonator are chosen from the group comprising W, Mo or Al.

9. The BAW resonator of claim 1:
wherein the coil comprises a first winding formed in a first metal layer and a second winding formed in a second metal layer;
wherein the two windings are circuited in series with each other by a via connecting the first ends in the middles of the respective windings; and
wherein a first one of the second ends of the series connection of the two windings are connected to the bottom electrode while the second one of the second ends is connected to the top electrode to circuit the coil in parallel to the BAW resonator.

10. The BAW resonator of claim 1, wherein at least one of the high impedance mirror layers is grounded.
